(19) United States
(12) Patent Application Publication
(10) Pub. No.: US 2019/0371718 A1
(43) Pub. Date: Dec. 5, 2019

(54) METHOD FOR MANUFACTURING SEMICONDUCTOR DEVICE

(71) Applicant: TAIWAN SEMICONDUCTOR MANUFACTURING COMPANY LTD., HSINCHU (TW)

(72) Inventors: HUA-WEI TSENG, NEW TAIPEI CITY (TW); CHITA CHUANG, HSINCHU CITY (TW); MING HUNG TSENG, MIAOLI COUNTY (TW); CHEN-SHIEN CHEN, HSINCHU COUNTY (TW); MIRNG-JI LII, HSINCHU COUNTY (TW)

(21) Appl. No.: 16/539,793

(22) Filed: Aug. 13, 2019

Related U.S. Application Data
(62) Division of application No. 14/471,179, filed on Aug. 28, 2014.

(51) Int. Cl. H01L 23/498

(52) U.S. Cl. CPC H01L 23/49827

(57) ABSTRACT

A method for manufacturing a semiconductor device includes following operations. A first substrate with a conductive pad is received. A connector is disposed over the conductive pad. A second substrate including a conductive land is provided. A position of the first substrate or the second substrate is adjusted thereby a geometric center of the conductive land is deviated from a geometric center of the connector in a deviated distance. The connector is bonded with the conductive land. A temperature of the semiconductor device is adjusted so as to control elongation of the first substrate and the second substrate, thereby the geometric center of the connector is substantially aligned with the geometric center of the conductive land.

### PRIORITY CLAIM AND CROSS-REFERENCE

This application is a divisional application of U.S. patent application Ser. No. 14/471,179, filed on Aug. 28, 2014, entitled of “SEMICONDUCTOR DEVICE AND MANUFACTURING METHOD THEREOF,” which is incorporated herein by reference in its entirety.

### BACKGROUND

Electronic equipment using semiconductor devices are essential for many modern applications. With the advancement of electronic technology, the semiconductor devices are becoming increasingly smaller in size while having greater functionality and greater amounts of integrated circuitry. Due to the miniaturized scale of the semiconductor device, a wafer level packaging (WLP) is widely used for its low cost and relatively simple manufacturing operations. During the WLP operation, a number of semiconductor components are assembled on the semiconductor device. Furthermore, numerous manufacturing operations are implemented within such a small semiconductor device.

However, the manufacturing operations of the semiconductor device involve many steps and operations on such a small and thin semiconductor device. The manufacturing of the semiconductor device in a miniaturized scale becomes more complicated. The semiconductor device is assembled with numbers of integrated components including various materials with difference in thermal properties. As such, the integrated components are in undesired configurations after curing of the semiconductor device. The undesired configurations would lead to yield loss of the semiconductor device, poor electrical interconnection, development of cracks or delamination of the components, etc. Furthermore, the components of the semiconductor device includes various metallic materials which are in limited quantity and thus in a high cost. The undesired configurations of the components and the yield loss of the semiconductor would further exacerbate materials wastage and thus the manufacturing cost would increase.

Since different components with different materials are involved, a complexity of the manufacturing operations of the semiconductor device is increased. There are more challenges to modify a structure of the semiconductor device, improve the manufacturing operations and minimize materials usage. As such, there is a continuous need to improve the manufacturing the semiconductor and solve the above deficiencies.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of a semiconductor device structure in accordance with some embodiments of the present disclosure.

FIG. 2 is a schematic view of a semiconductor device structure including several connectors on a substrate in accordance with some embodiments of the present disclosure.

FIG. 3 is a schematic view of a semiconductor device structure with a geometric center of a connector deviated from a geometric center of a conductive land in accordance with some embodiments of the present disclosure.

FIG. 4 is a schematic view of a semiconductor device structure with a via and a via pad under a conductive land in accordance with some embodiments of the present disclosure.

FIG. 5 is a schematic view of a semiconductor device structure with a guide pin on a conductive land in accordance with some embodiments of the present disclosure.

FIG. 6 is a schematic view of a semiconductor device structure with a geometric center of a connector deviated from a geometric center of a tapered metallic plug in accordance with some embodiments of the present disclosure.

FIG. 7 is a schematic view of a semiconductor device structure with a geometric center of a connector aligned with a geometric center of a conductive land and a geometric center of a conductive pad in accordance with some embodiments of the present disclosure.

FIG. 8 is a schematic view of a semiconductor device structure with a geometric center of a connector aligned with a geometric center of a conductive land and a geometric center of a via in accordance with some embodiments of the present disclosure.

FIG. 9 is a schematic view of a semiconductor device structure with a geometric center of a connector aligned with a geometric center of a conductive land and a geometric center of a tapered metallic plug in accordance with some embodiments of the present disclosure.

FIG. 10 is a flow diagram of a method of manufacturing a semiconductor device in accordance with some embodiments of the present disclosure.

FIG. 11A is a schematic view of a first substrate in accordance with some embodiments of the present disclosure.

FIG. 11B is a schematic view of a connector disposed on a first substrate in accordance with some embodiments of the present disclosure.

FIG. 11C is a schematic view of a first substrate and a second substrate in accordance with some embodiments of the present disclosure.

FIG. 11D is a schematic view of a first substrate and a second substrate with a via and a via pad in accordance with some embodiments of the present disclosure.

FIG. 11E is a schematic view of a first substrate and a second substrate with a guide pin in accordance with some embodiments of the present disclosure.

FIG. 11F is a schematic view of a first substrate and a second substrate with a tapered metallic plug in accordance with some embodiments of the present disclosure.

FIG. 11G is a schematic view of aligning a geometric center of a conductive pad with a geometric center of a conductive land in accordance with some embodiments of the present disclosure.

FIG. 11H is a schematic view of aligning a geometric center of a conductive pad with a geometric center of a via in accordance with some embodiments of the present disclosure.

FIG. 11I is a schematic view of aligning a geometric center of a conductive pad with a geometric center of a guide pin in accordance with some embodiments of the present disclosure.

FIG. 11J is a schematic view of aligning a geometric center of a conductive pad with a geometric center of a tapered metallic plug in accordance with some embodiments of the present disclosure.

FIG. 11K is a schematic view of a first substrate bonded with a second substrate in accordance with some embodiments of the present disclosure.

FIG. 11L is a schematic view of a first substrate bonded with a second substrate having a via in accordance with some embodiments of the present disclosure.

FIG. 11M is a schematic view of a first substrate bonded with a second substrate having a guide pin in accordance with some embodiments of the present disclosure.

FIG. 11N is a schematic view of a first substrate bonded with a second substrate having a tapered metallic plug in accordance with some embodiments of the present disclosure.

FIG. 11O is a schematic view of aligning a geometric center of a connector with a geometric center of a conductive land and a geometric center of a conductive pad in accordance with some embodiments of the present disclosure.

FIG. 11P is a schematic view of aligning a geometric center of a connector with a geometric center of a conductive land and a geometric center of a via in accordance with some embodiments of the present disclosure.

FIG. 11Q is a schematic view of aligning a geometric center of a connector with a geometric center of a conductive land, a geometric center of a guide pin and a geometric center of a conductive pad in accordance with some embodiments of the present disclosure.

FIG. 11R is a schematic view of aligning a geometric center of a connector with a geometric center of a conductive land, a geometric center of a tapered metallic plug and a geometric center of a conductive pad in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device is assembled with another substrate or circuit board to become a semiconductor package. Several conductive bumps on the semiconductor device are bonded with corresponding bond pads of the substrate or circuit board to form an interconnection. Each conductive bump is precisely aligned with the corresponding pad, so that the conductive bump is landed at a central area of the bond pad. Thus, an adhesion between the conductive bump and the bond pad is maximized and delamination of the interconnection is minimized.

However, the semiconductor device includes various kinds of components such as substrate, bond pad and conductive bumps. Each of the components includes different types of materials with different thermal properties. The conductive bumps are bonded with bond pads of another substrate or circuit board through a reflow operation under a high temperature. After the reflow operation, the semiconductor device is cooled down from reflow (high) temperature to a room (low) temperature. Since different materials have different coefficient of thermal expansion (CTE), the components are expanded or shrunk in different rates. The conductive bump is finally misaligned with the bond pad. As a result, delamination of the interconnection is occurred.

Furthermore, a thermal stress is developed in the semiconductor device due to a mismatch of coefficient of thermal expansion (CTE) of the components of the semiconductor device. As a result, adhesion between the conductive bump and the bond pad is decreased, and cracks are developed within the semiconductor device. Therefore, some modifications and improvements on the semiconductor device are desired in order to strengthen the interconnection and lower the internal stress.

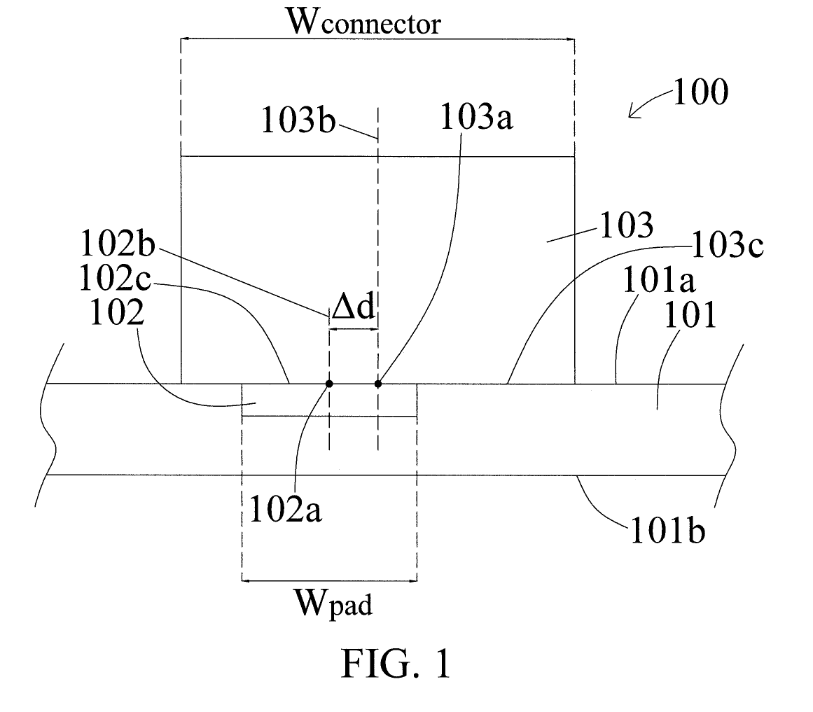

FIG. 1 is a semiconductor device 100 in accordance with various embodiments of the present disclosure. FIG. 1 shows a cross sectional view of the semiconductor device 100. In some embodiments, the semiconductor device 100 is a semiconductor die. In some embodiments, the semiconductor device 100 includes a substrate 101, a conductive pad 102 and a connector 103.

In some embodiments, the substrate 101 is a piece including semiconductor materials such as silicon, germanium, gallium arsenic or etc. In some embodiments, the substrate 101 is fabricated with a predetermined functional circuit. In some embodiments, the substrate 101 includes a first surface 101a and a second surface 101b opposite to the first surface 101a. In some embodiments, the first surface 101a is a front side or an active side, while the second surface 101b is a back side. In some embodiments, several active devices (not shown) such as transistors are formed at the first surface 101a of the substrate 101.

The conductive pad 102 is disposed at or over the first surface 101a of the substrate 101. In some embodiments, the conductive pad 102 is electrically connected with a circuitry of the substrate 101. In some embodiments, the conductive pad 102 includes aluminum (Al), copper (Cu), tin (Sn), nickel (Ni), gold (Au), silver (Ag), other electrically conductive materials, alloy thereof or multi layers thereof.

In some embodiments, the conductive pad 102 has a surface area 102c along the first surface 101a in a circular, elliptical, rectangular, quadrilateral or polygonal shape. In some embodiments, the conductive pad 102 has a width W_{pad} of about 20 μm to about 200 μm.

In some embodiments, the conductive pad 102 is defined with a geometric center 102a. In some embodiments, the geometric center 102a is defined at the surface area 102c of the conductive pad 102. In some embodiments, a longest diagonal of the surface area 102c of the conductive pad 102 passes through the geometric center 102a. In some embodiments, the conductive pad 102 is defined with a central axis 102b passing through the geometric center 102a and substantially orthogonal to the surface area 102c.

The connector 103 overlies the conductive pad 102. In some embodiments, the connector 103 is disposed over the conductive pad 102. In some embodiments, the connector 103 is a protrusion or pillar protruding from the conductive pad 102 or the substrate 101. In some embodiments, the connector 103 is protruded from the first surface 101a of the substrate 101. In some embodiments, the connector 103 is protruded from the surface area 102c of the conductive pad 102. In some embodiments, at least a portion of the connector 103 is contacted and electrically connected with the conductive pad 102. In some embodiments, a contact interface between the connector 103 and the conductive pad 102 is of a shape of a circle, an octagon, a rectangle, an oval or a diamond.

In some embodiments, the connector 103 is configured to be electrically connected with a conductive land of another substrate, so that the circuitry of the substrate 101 can be electrically connected with a circuitry of another substrate external to the substrate 101. In some embodiments, the connector 103 includes copper (Cu), gold (Au), platinum (Pt), titanium (Ti), nickel (Ni), aluminum (Al), etc.

In some embodiments, the connector 103 has a surface area 103c along the first surface 101a in a circular, elliptical, rectangular, quadrilateral or polygonal shape. In some embodiments, the connector 103 has a width W_{connector} substantially greater than the width W_{pad} of the conductive pad 102. In some embodiments, the width W_{connector} is about 20 μm to about 200 μm.

In some embodiments, the connector 103 is defined with a geometric center 103a. In some embodiments, the geometric center 103a is defined at the surface area 103c of the connector 103. In some embodiments, a longest diagonal of the surface area 103c of the connector 103 passes through the geometric center 103a. In some embodiments, the connector 103 is defined with a central axis 103b passing through the geometric center 103a and substantially orthogonal to the surface area 103c.

In some embodiments, the connector 103 is not aligned with the conductive pad 102. The geometric center 103a of the connector 103 is not aligned or not overlapped with the geometric center 102a of the conductive pad 102. The geometric center 103a of the connector 103 is deviated from the geometric center 102a of the conductive pad 102 in a distance Δd. In some embodiments, the geometric center 103a of the connector 103 is deviated from the geometric center 102a of the conductive pad 102 and a geometric center of a conductive land of another substrate. In some embodiments, the distance Δd is about 10 μm to about 50 μm. In some embodiments, the central axis 102b of the conductive pad 102 is not aligned with the central axis 103b of the connector 103. The central axis 102b is deviated from the central axis 103 in the distance Δd.

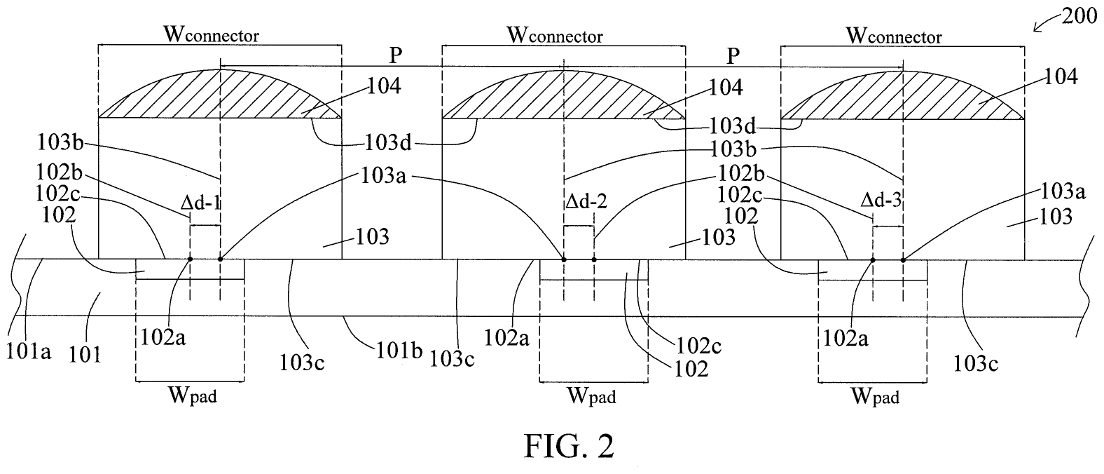

FIG. 2 is a semiconductor device 200 in accordance with various embodiments of the present disclosure. FIG. 2 shows a cross sectional view of the semiconductor device 200. In some embodiments, the semiconductor device 200 is includes a substrate 101, a plurality of conductive pads 102 and a plurality of corresponding connectors 103. The substrate 101, the conductive pad 102 and the connector 103 have similar configuration as in FIG. 1.

In some embodiments, the conductive pads 102 are disposed over the first surface 101a of the substrate 101 and are consistent in shape and dimension. The conductive pads 102 have same width W_{pad} as each other. In some embodiments, the connectors 104 are disposed over the conductive pads 102 correspondingly and are consistent in shape and dimension. The connectors 104 have same width W_{connector} as each other.

In some embodiments, a geometric center 102a of each conductive pad 102 is deviated from a geometric center 103a of the corresponding connector 103. The geometric centers 102a are deviated from the geometric centers 103a respectively in distances Δd-1, Δd-2, Δd-3. In some embodiments, the distances Δd-1, Δd-2, Δd-3 are consistent to or different from each other. Similarly, a central axis 102b of each conductive pad 102 is deviated from a central axis 103b of the corresponding connector 103 in the distances Δd-1, Δd-2, Δd-3.

There is a pitch P between neighboring connectors 103. In some embodiments, the pitch P is a distance between the geometric center 102a of the conductive pad 102 and the geometric center 103a of the connector 103. In some embodiments, the pitch P is a distance between the central axis 102b of the conductive pad 102 and the central axis 103b of the connector 103. In some embodiments, the pitch P is about 50 μm to about 150 μm. In some embodiments, the pitches P between each of the connectors 103 are consistent or different from each other.

In some embodiments, a solder 104 is disposed on a top 103d of the connector 103. In some embodiments, the solder 104 is a solder paste mixture of metallic powders and flux. In some embodiments, the solder 104 includes lead, tin copper, gold, nickel, etc. or metal alloy thereof The solder 104 is configured to become in contact with the conductive land of another substrate.

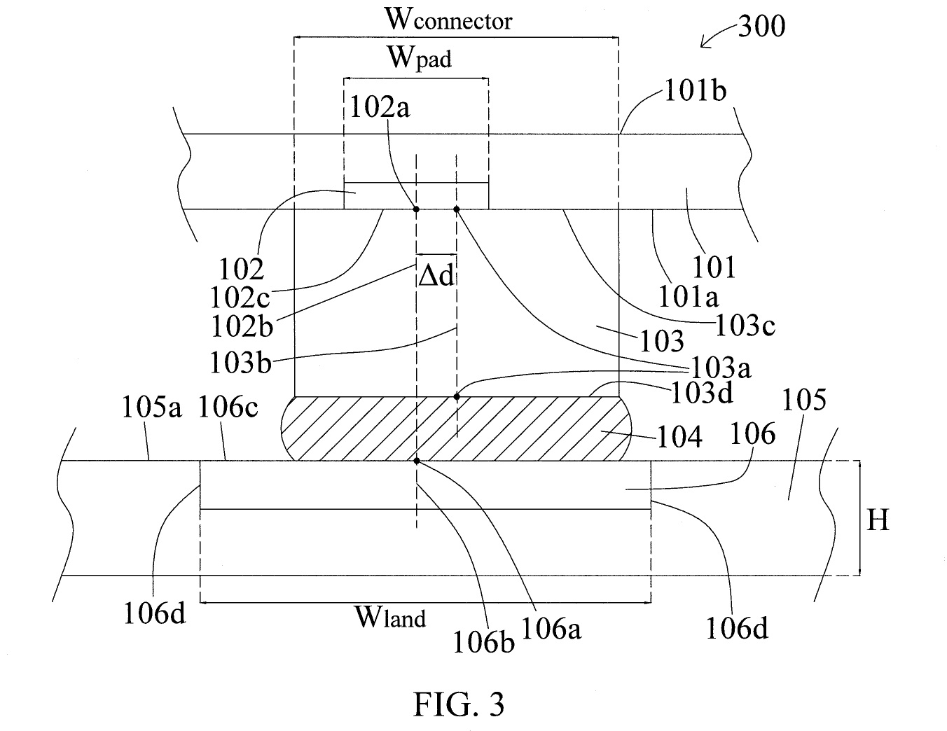

FIG. 3 is a semiconductor device 300 in accordance with various embodiments of the present disclosure. FIG. 3 shows a cross sectional view of the semiconductor device 300. In some embodiments, the semiconductor device 300 is includes a first substrate 101, a conductive pad 102, a connector 103 and a solder 104, which have similar configuration as in FIG. 1 or FIG. 2. The connector 103 is protruded from the conductive pad 102 at a surface 101a of the first substrate 101.

The semiconductor device 300 further includes a second substrate 105. In some embodiments, the second substrate 105 includes a plurality of dielectric layers and conductors stacked together without an intervening core. In some embodiments, the second substrate 105 is a coreless substrate or an embedded pattern plating (EPP) substrate. In some embodiments, the second substrate 105 has a coefficient of thermal expansion (CTE) substantially larger than a CTE of the first substrate 101. The second substrate 105 has greater expansion or elongation in all direction than the first substrate 101 when the semiconductor device 300 is heated to a predetermined temperature. In some embodiments, the second substrate 105 is thin and small in thickness. In some embodiments, the second substrate 105 has a thickness H of about 30 μm to about 600 μm.

In some embodiments, the second substrate 105 includes a conductive land 106, which is configured to be in contact with the connector 104 of the first substrate 101. The conductive land 106 is disposed over a surface 105a of the second substrate 102. In some embodiments, the conductive land 106 is electrically connected with a circuitry of the second substrate 105. In some embodiments, the conductive land 106 includes aluminum (Al), copper (Cu), tin (Sn), nickel (Ni), gold (Au), silver (Ag), other electrically conductive materials, alloy thereof or multi layers thereof.

In some embodiments, the conductive land 106 has a surface area 106c along the surface 105a in a circular, elliptical, rectangular, quadrilateral or polygonal shape. In some embodiments, the conductive land 106 has a width W_{land} of about 80 μm to about 120 μm.

In some embodiments, the conductive land 106 is defined with a geometric center 106a. In some embodiments, the geometric center 106a is defined at the surface area 106c of the conductive land 106. In some embodiments, a longest diagonal of the surface area 106c of the conductive land 106 passes through the geometric center 106a. In some embodiments, the conductive land 106 is defined with a central axis 106b passing through the geometric center 106a and substantially orthogonal to the surface area 106c.

The connector 103 of the first substrate 101 is contacted with the conductive land 106 by the solder 104. In some embodiments, the conductive land 106 of the second substrate 105 is in alignment with the conductive pad 102 of the first substrate 101, such that the geometric center 106a of the conductive land 106 is aligned with the geometric center 102a of the conductive pad 102. In some embodiments, the central axis 102b of the conductive pad 102 is overlapped and common with the central axis 106b of the conductive land 106.

In some embodiments, the geometric center 103a of the connector 103 is defined at the top 103d of the connector 103. The geometric center 103a of the connector 103 is deviated from the geometric center 106a of the conductive land 106 in a distance Δd. In some embodiments, the geometric center 103a of the connector 103 is deviated from the geometric center 102a of the conductive pad 102 and the geometric center 106a of the conductive land 106. In some embodiments, the distance Δd is about 10 μm to about 50 μm.

In some embodiments, the deviation of the geometric center 103a of the connector 103 from the geometric center 106a of the conductive land 106 or the geometric center 102a of the conductive pad 102 is restrained by the width W_{land} of the conductive land 106. The deviation of the geometric center 103a of the connector 103 from the geometric center 106a of the conductive land 106 or the geometric center 102a of the conductive pad 102 has a limitation, that the connector 103 must be disposed within an external boundary 106d of the conductive land 106.

In some embodiments, the width W_{land} of the conductive land 106 is x μm, the width W_{connector} of the connector 103 is y μm, and the geometric center 103a of the connector 103 deviated from the geometric center 106a of the conductive land 106 or the geometric center 102a of the conductive pad 102 in the distance Δd μm. The width W_{land}×μm is greater than or equal to the width W_{connector} y μm plus 2 times of the distance Δd μm (x≥y+2Δd). Thus, the connector 103 must be disposed within the external boundary 106d of the conductive land 106.

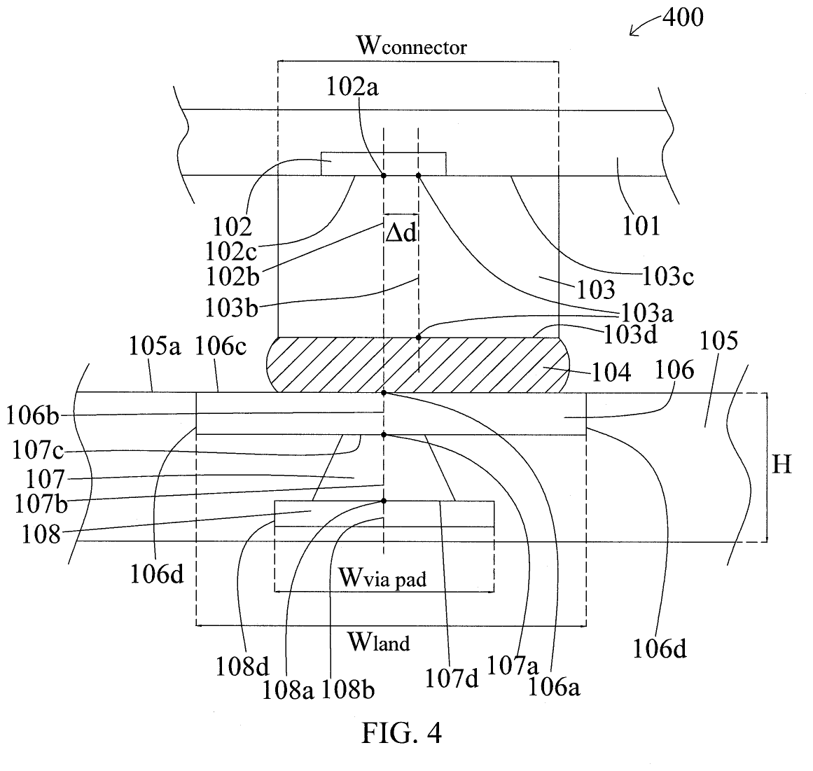

In some embodiments as in FIG. 4, the second substrate 105 further includes a via 107 disposed under the conductive land 106. The via 107 is extended between the conductive land 106 and a via pad 108. The via 107 is extended and passed through the dielectric layers of the second substrate 105, such that the conductive land 106 is electrically connected with the via pad 108 or the circuitry of the second substrate 105.

In some embodiments, the via 107 is tapered from the conductive land 106 towards the via pad 108 or vice versa. In some embodiments, a first surface 107c of the via 107 is smaller or greater than a second surface 107d of the via 107. In some embodiments, the width W_{land} of the conductive land 106 is substantially greater than a width W_{via pad} of the via pad 108. In some embodiments, the via 107 is disposed within the conductive land 106 and the via pad 108. The via 107 is bounded by the external boundary 106d of the conductive land 106 and an external boundary 108d of the via pad 108.

In some embodiments, a geometric center 107a of the via 107 is aligned with the geometric center 106a of the conductive land 106. A central axis 107b of the via 107 is common with the central axis 106b of the conductive land 106. In some embodiments, the geometric center 107a of the via 107 is aligned with the geometric center 102a of the conductive pad 102, that the central axis 107b of the via 107 is common with the central axis 102b of the conductive pad 102. In some embodiments, the geometric center 103a of the connector 103 is deviated from the geometric center 107a of the via 107 in the distance Δd. The central axis 103b of the connector 103 is deviated from the central axis 107 of the via 107 in the distance Δd.

In some embodiments, a geometric center 108a of the via pad 108 is aligned with the geometric center 107a of the via 107 or the geometric center 106a of the conductive land 106. A central axis 108b of the via pad 108 is common with the central axis 107b of the via 107 or the central axis 106b of the conductive land 106.

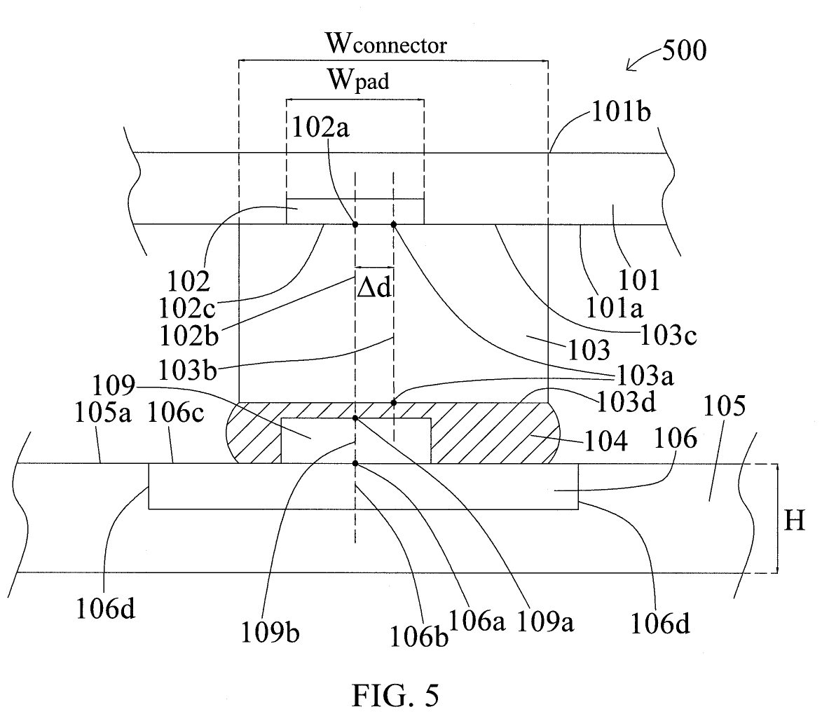

In some embodiments as in FIG. 5, a guide pin 109 is disposed on the conductive land 106. The guide pin 109 is protruded from the surface 105a of the second substrate 105 facing the conductive pad 102. In some embodiments, the guide pin 109 is configured to be in contact with the connector 103 or the solder 104. In some embodiments, a geometric center 109a of the guide pin 109 is aligned with the geometric center 106a of the conductive land 106. A central axis 109b of the guide pin 109 is common with the central axis 106b of the conductive land 106.

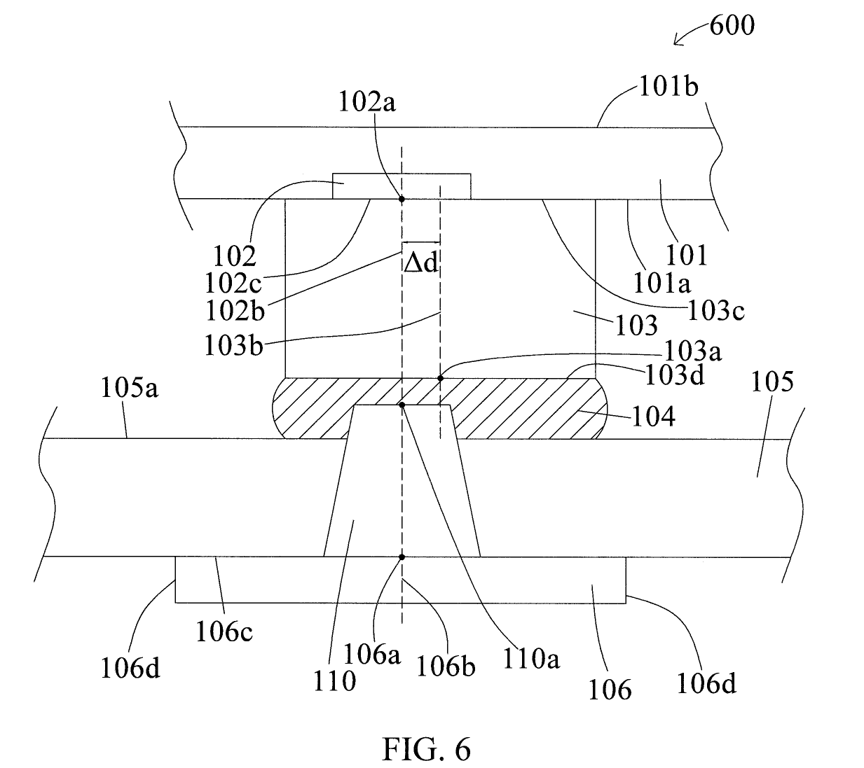

FIG. 6 is a semiconductor device 600 in accordance with various embodiments of the present disclosure. In some embodiments, the second substrate 105 of the semiconductor device 600 includes a tapered metallic plug 110 protruded from the surface 105a of the second substrate 105. The tapered metallic plug 110 is coupled with the conductive land 106. In some embodiments, the geometric center 102a of the conductive pad 102 is aligned with a geometric center 110a of the tapered metallic plug 110. In some embodiments, the geometric center 103a of the connector 103 is deviated in the distance Δd from the geometric center 102a of the conductive pad 102, the geometric center 106a of the conductive land 106 and the geometric center 110a of the tapered metallic plug 110.

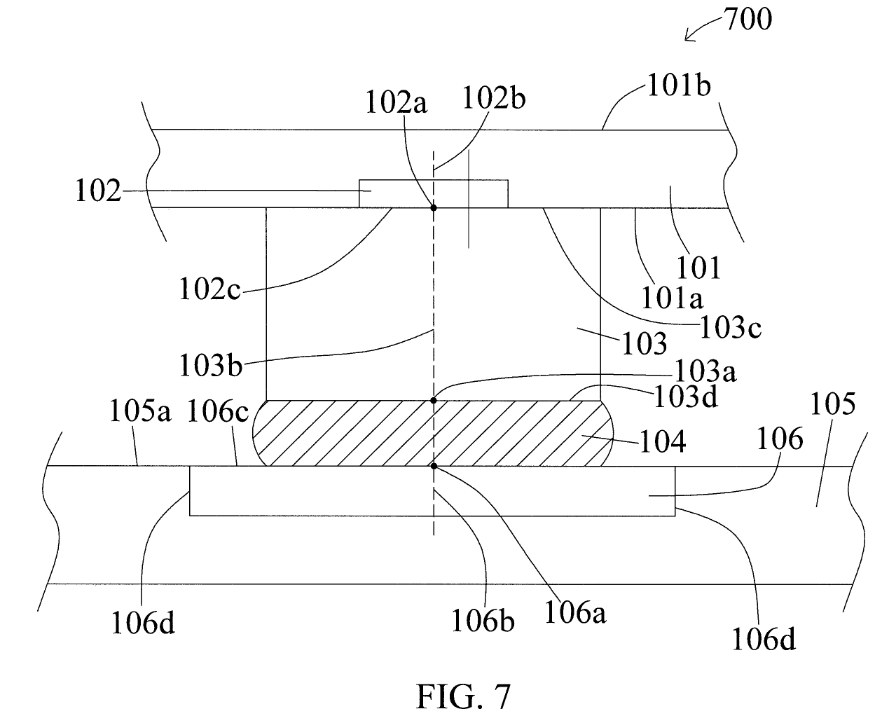

In some embodiments as in FIG. 7, the geometric center 102a of the conductive pad 102, the geometric center 103a of the connector 103 and the geometric center 106a of the conductive land 106 are aligned with each other when the semiconductor device 300 of FIG. 3 is heated to the predetermined temperature of about 200 to about 300 degrees Celsius to become the semiconductor device 700 of FIG. 7.

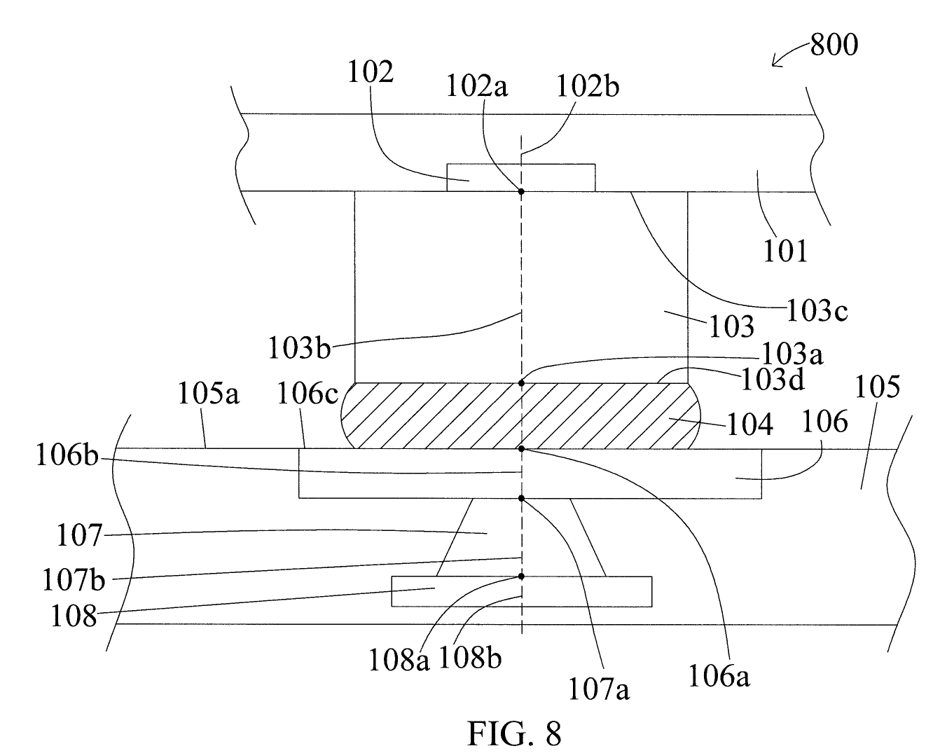

Similarly, the semiconductor device 400 of FIG. 4 becomes the semiconductor device 800 of FIG. 8 when heated to the predetermined temperature. In some embodiments, the geometric center 103a of the connector 103, the geometric center 106a of the conductive land 106 and the geometric center 107a of the via 107 are aligned when the semiconductor device 400 is heated to the predetermined temperature of about 200 to about 300 degrees Celsius.

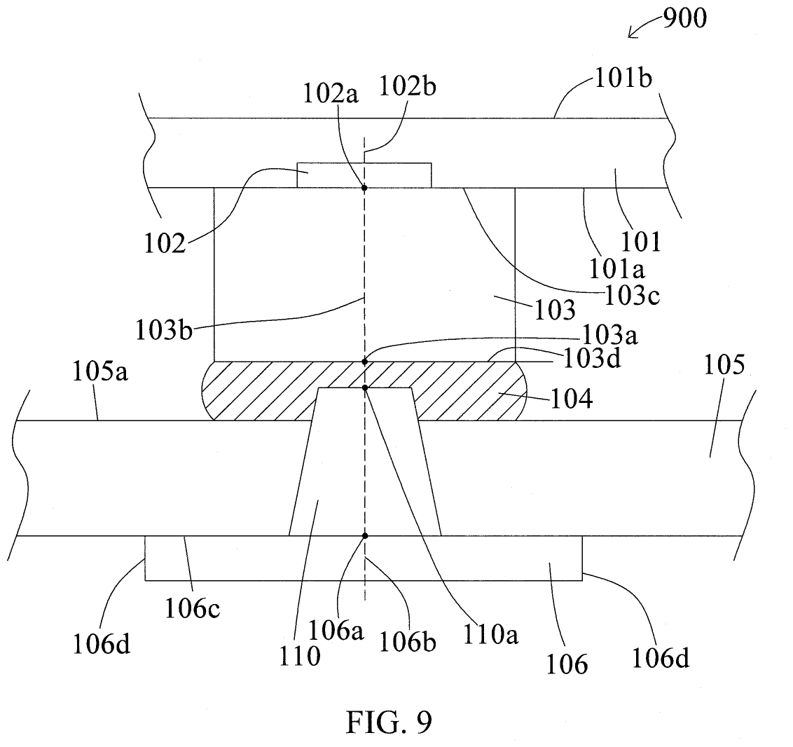

Similarly, the semiconductor device 600 of FIG. 6 becomes the semiconductor device 900 of FIG. 9 when heated to the predetermined temperature. In some embodiments as in FIG. 9, the geometric center 102a of the conductive pad 102, the geometric center 103a of the connector 103, the geometric center 110a of the tapered metallic plug 110 and the geometric center 103a of the connector 103 are aligned with each other when the semiconductor device 600 of FIG. 6 is heated to the predetermined temperature of about 200 to about 300 degrees Celsius to become the semiconductor device 900 of FIG. 9.

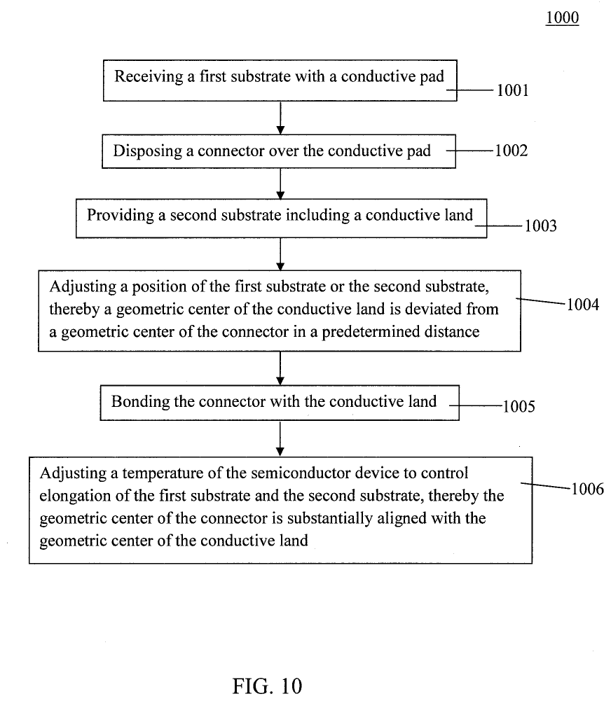

In the present disclosure, a method of manufacturing a semiconductor device is also disclosed. In some embodiments, a semiconductor device is formed by a method 1000. The method 1000 includes a number of operations and the description and illustration are not deemed as a limitation as the sequence of the operations. FIG. 10 is a diagram of a method 1000 of manufacturing a semiconductor device in accordance with various embodiments of the present disclosure. The method 1000 includes a number of operations (1001, 1002, 1003, 1004, 1005 and 1006).

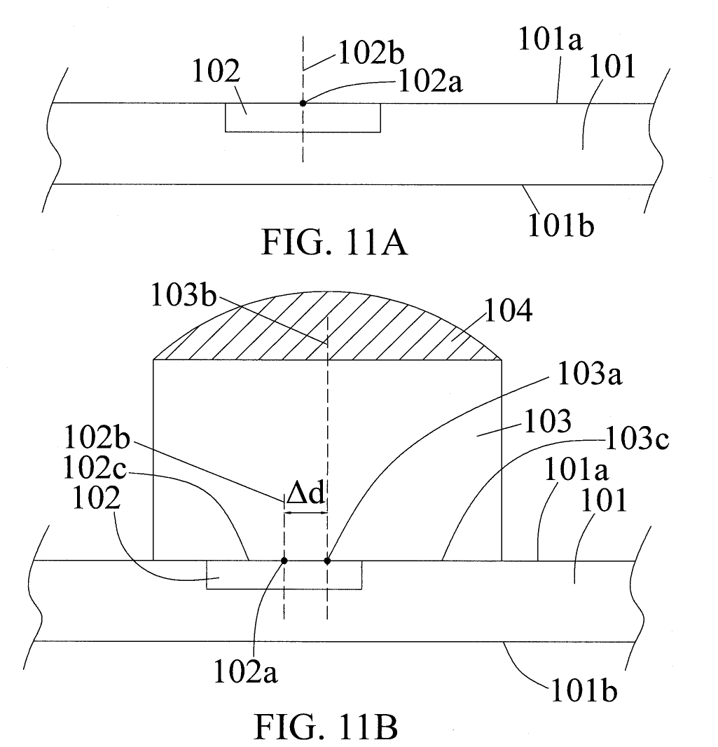

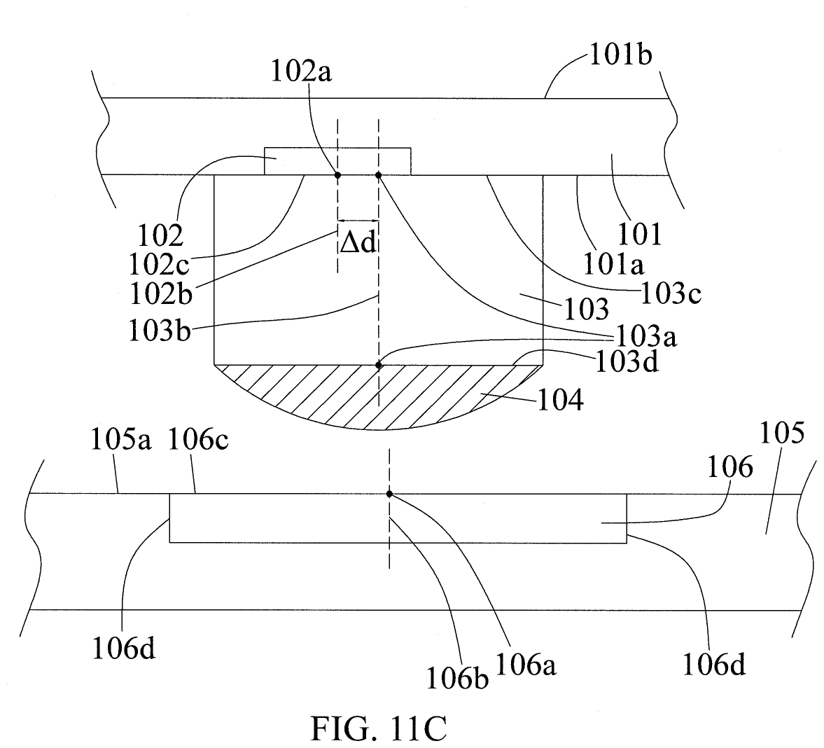

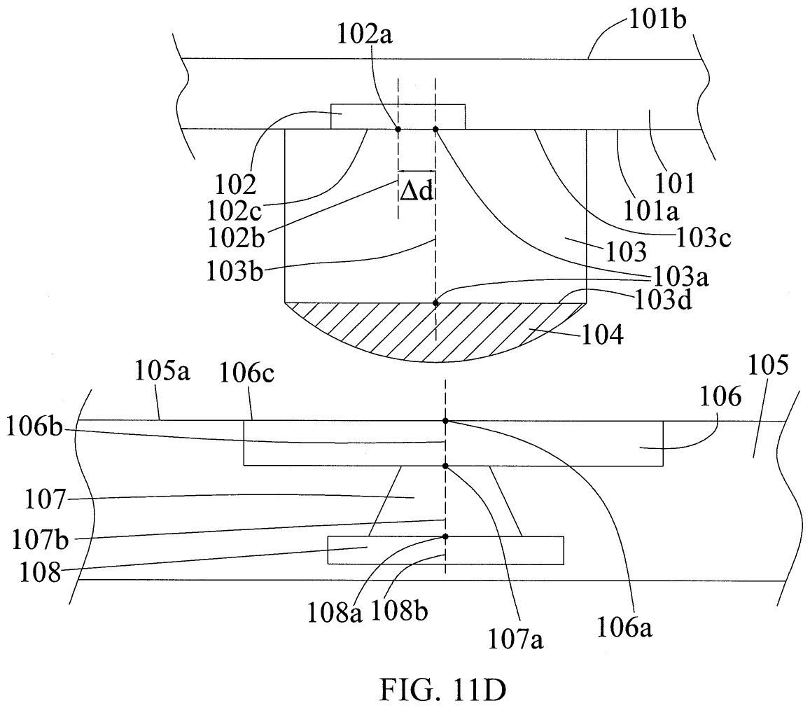

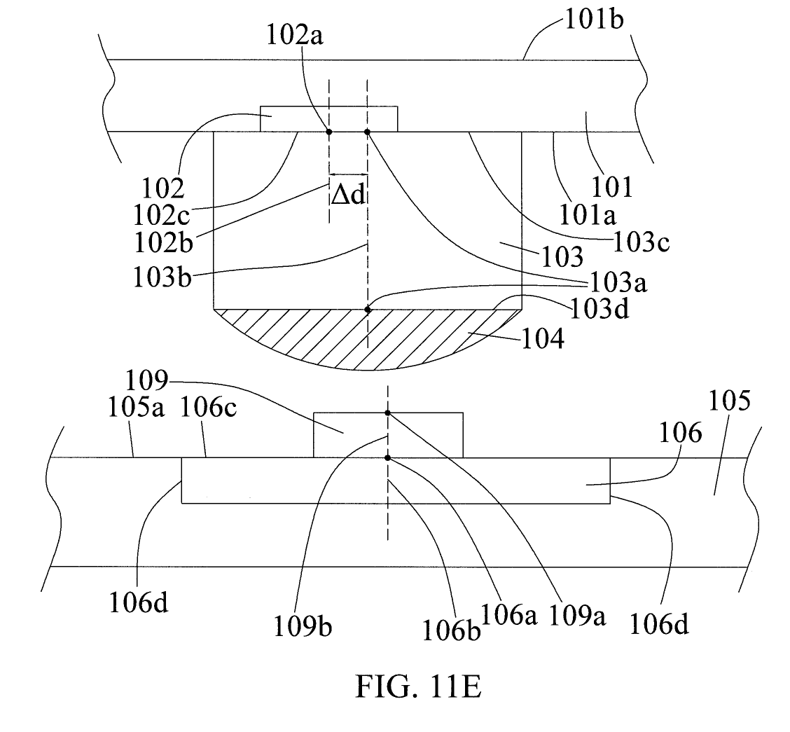

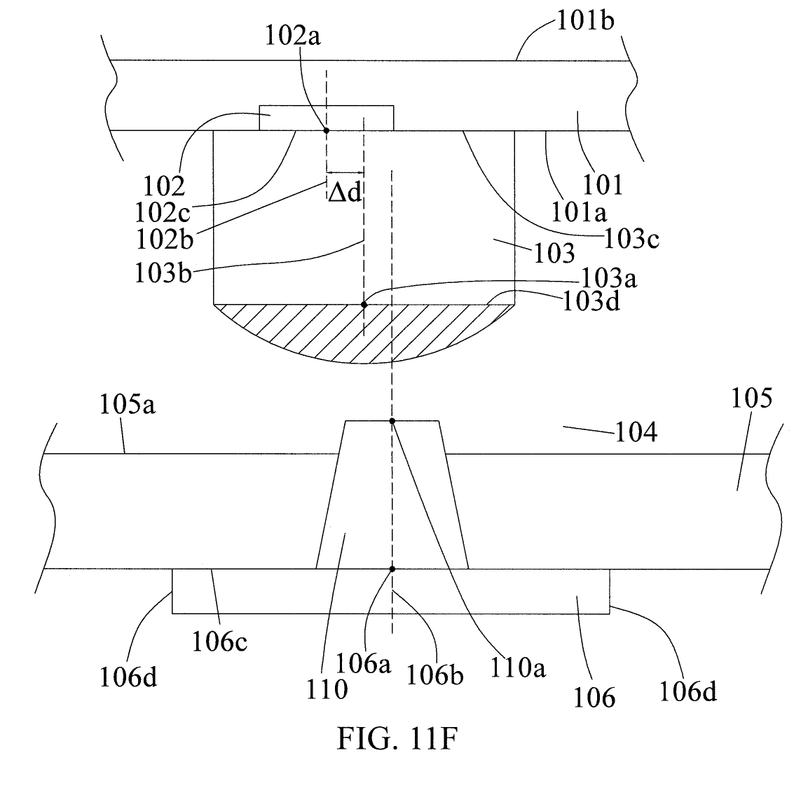

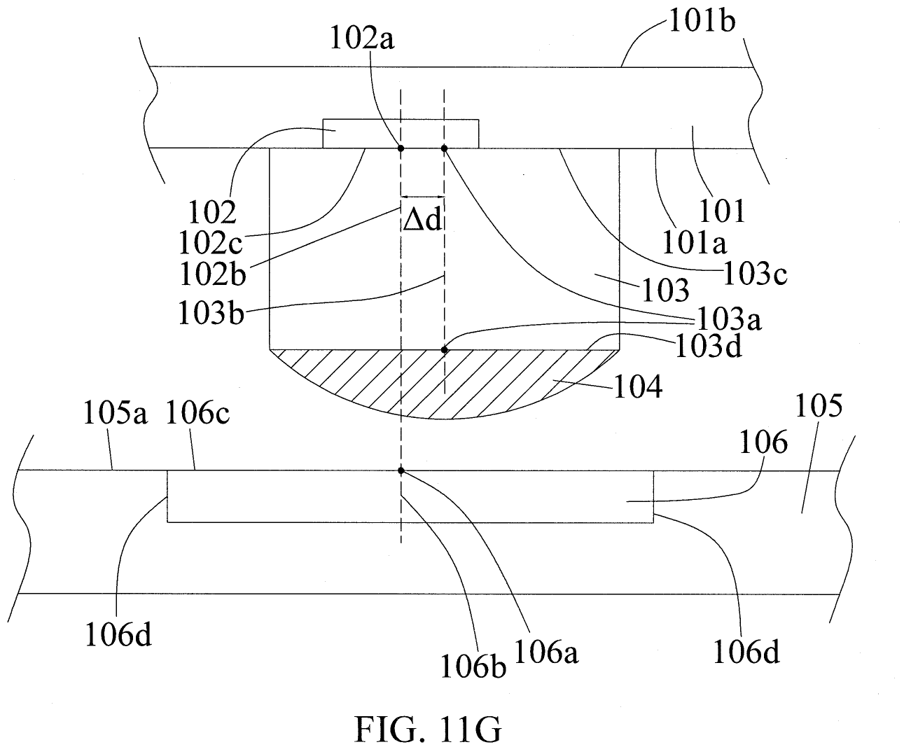

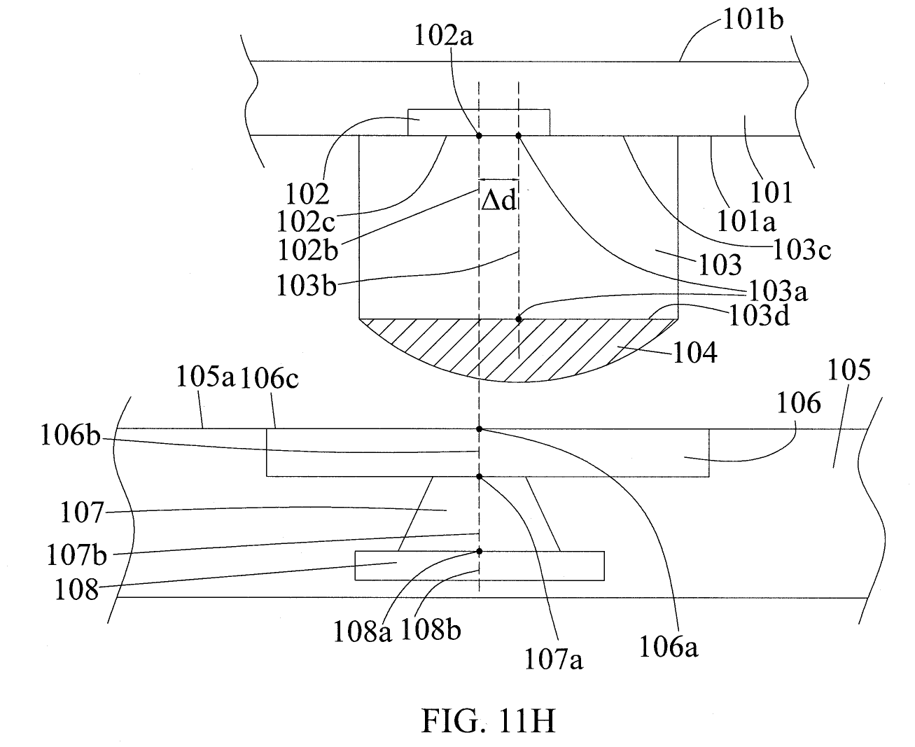

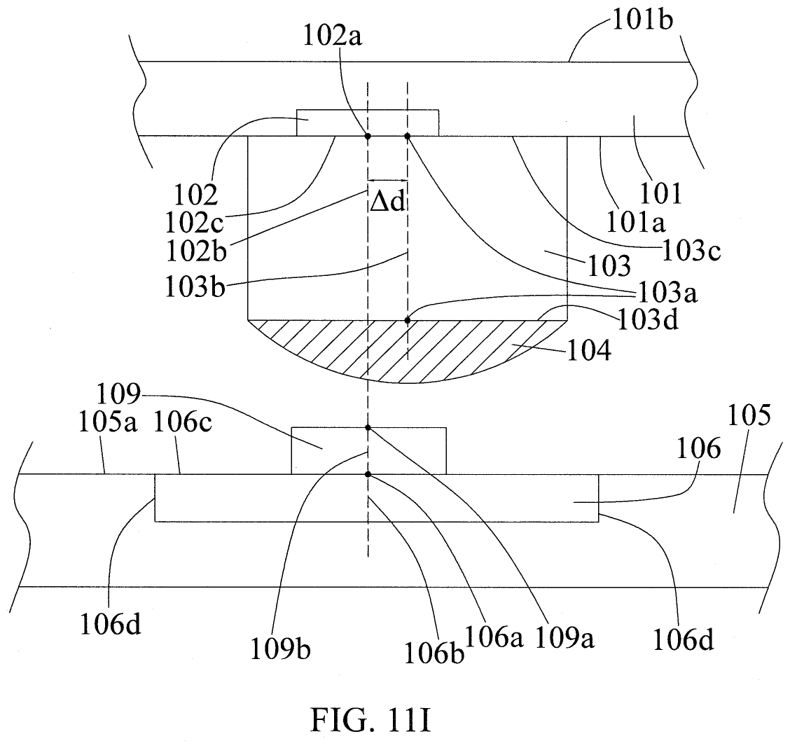

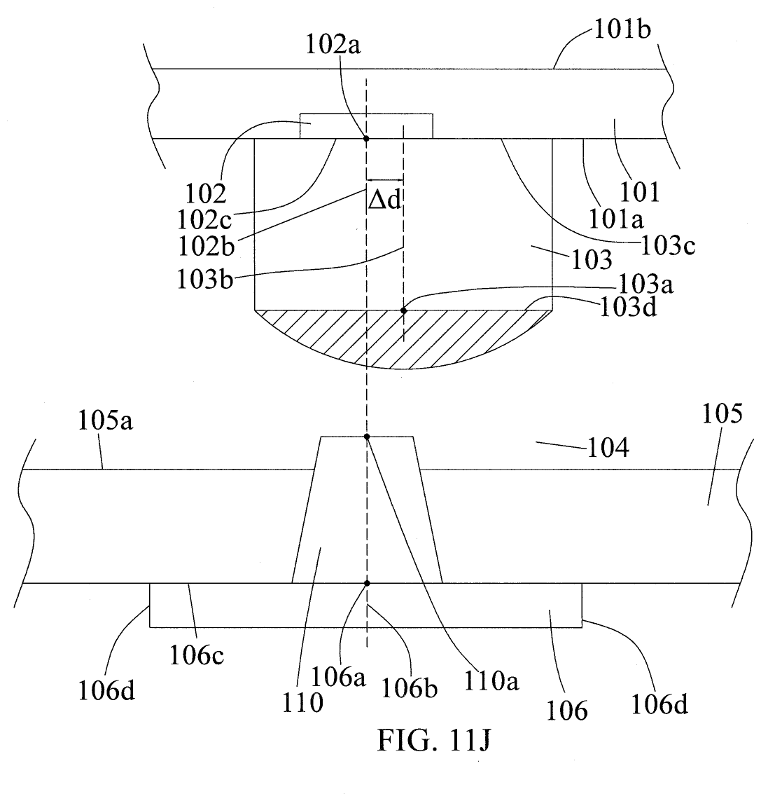

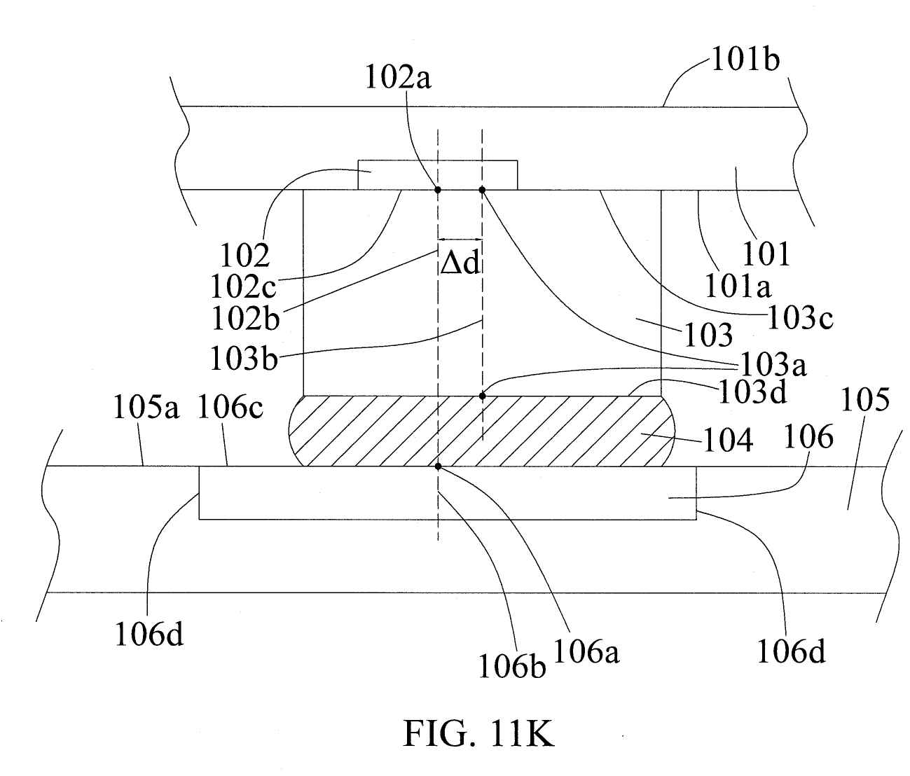

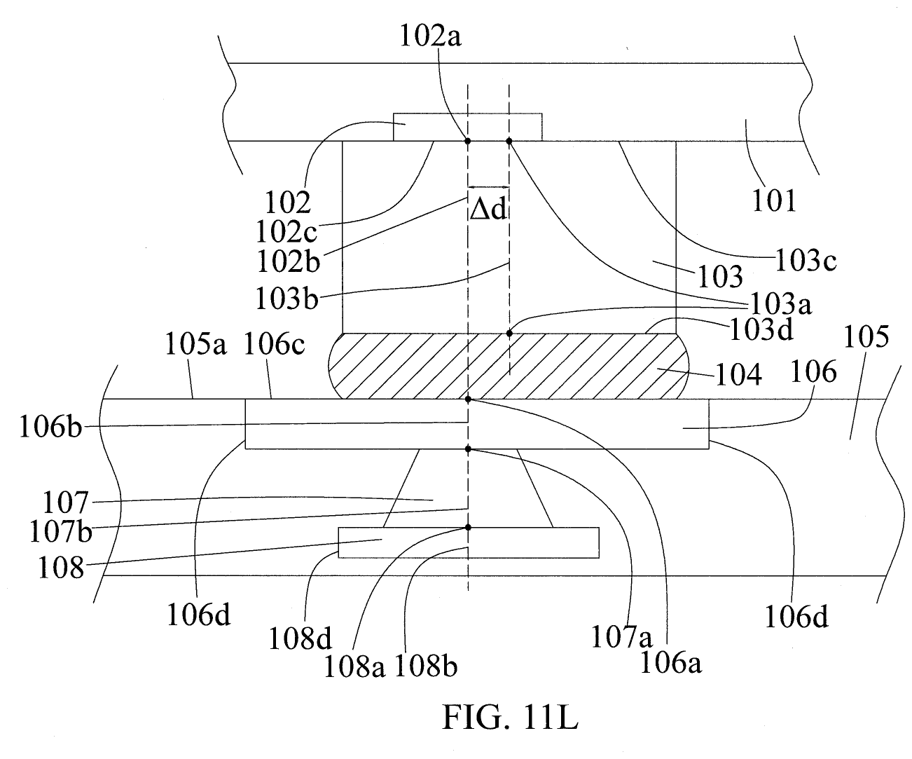

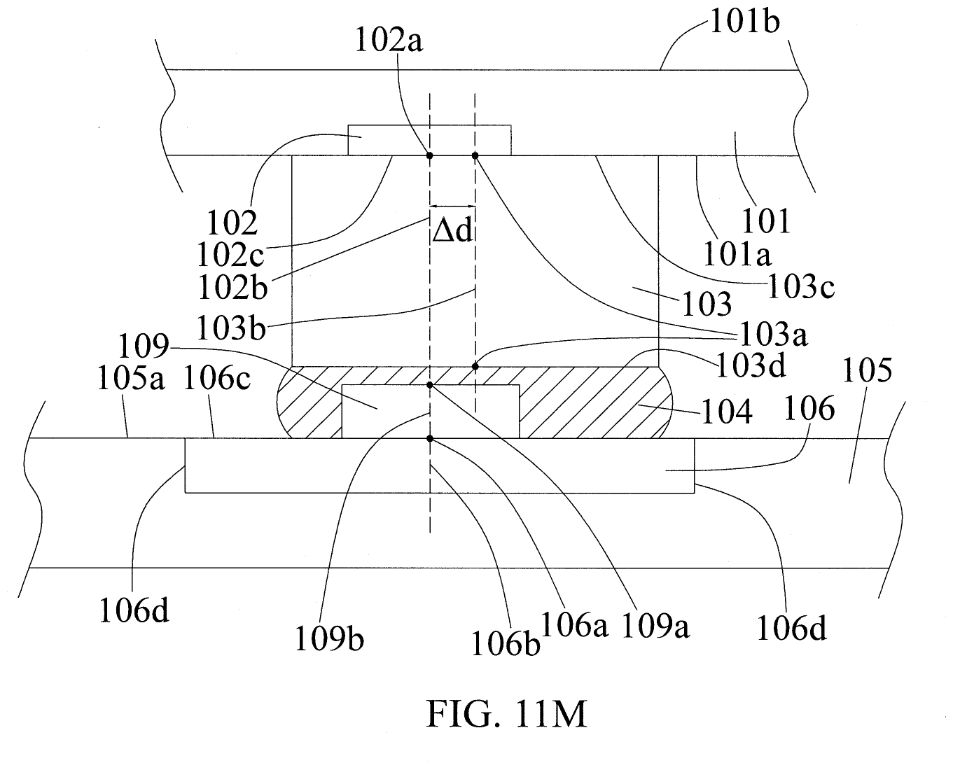

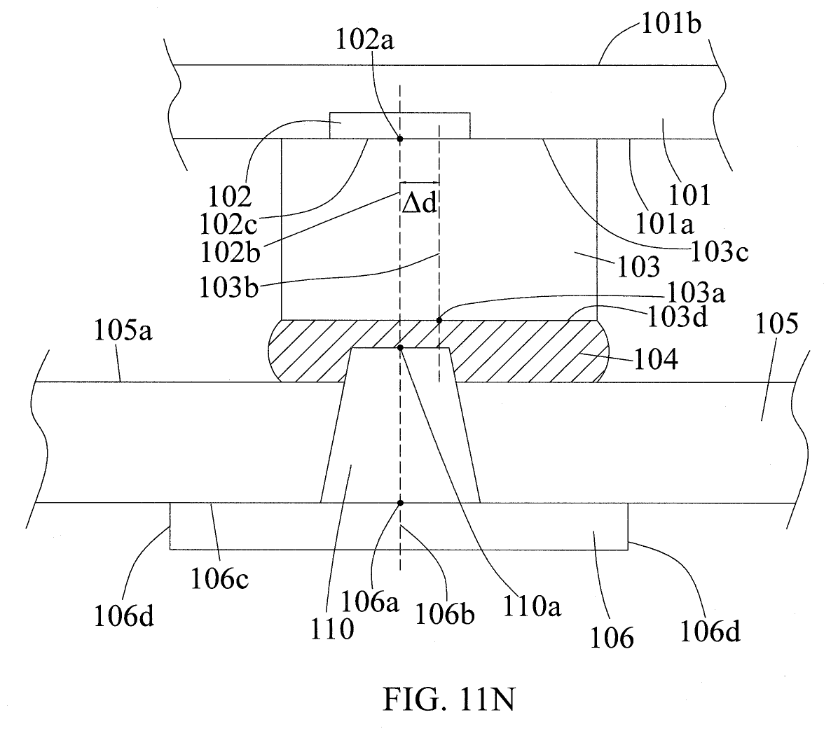

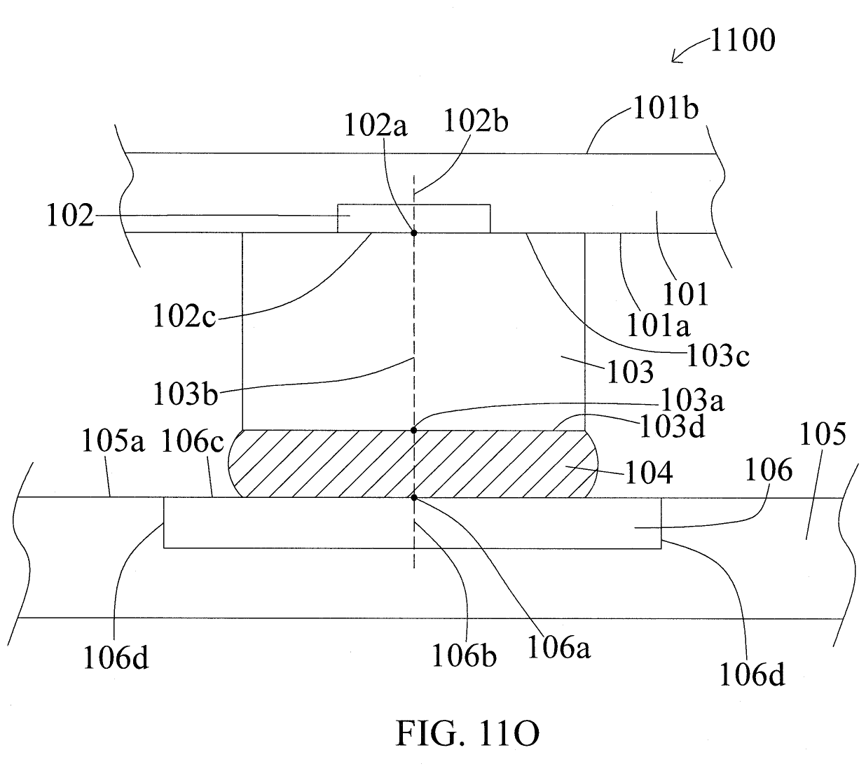

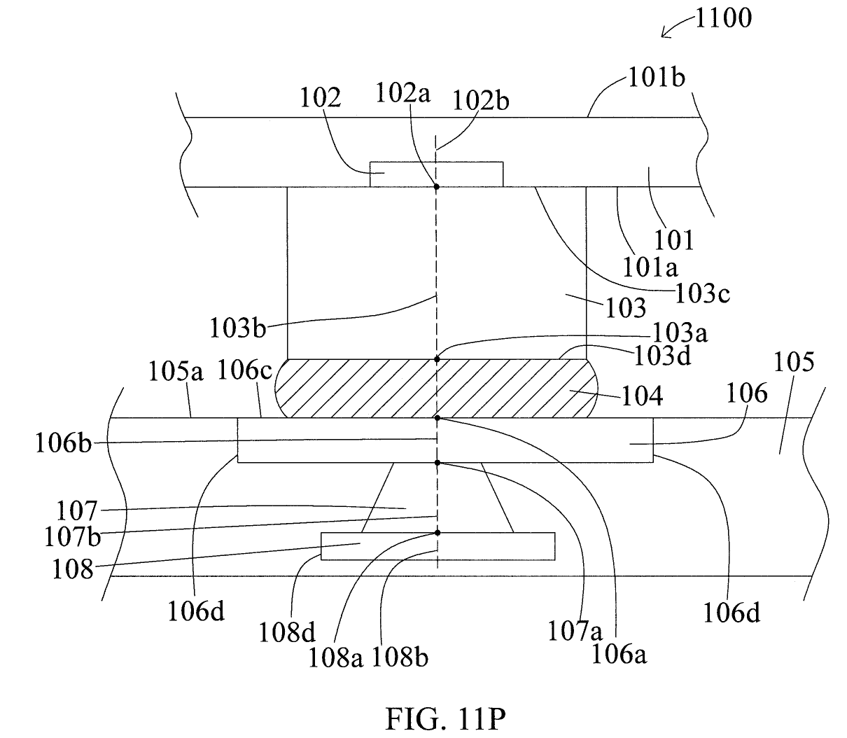

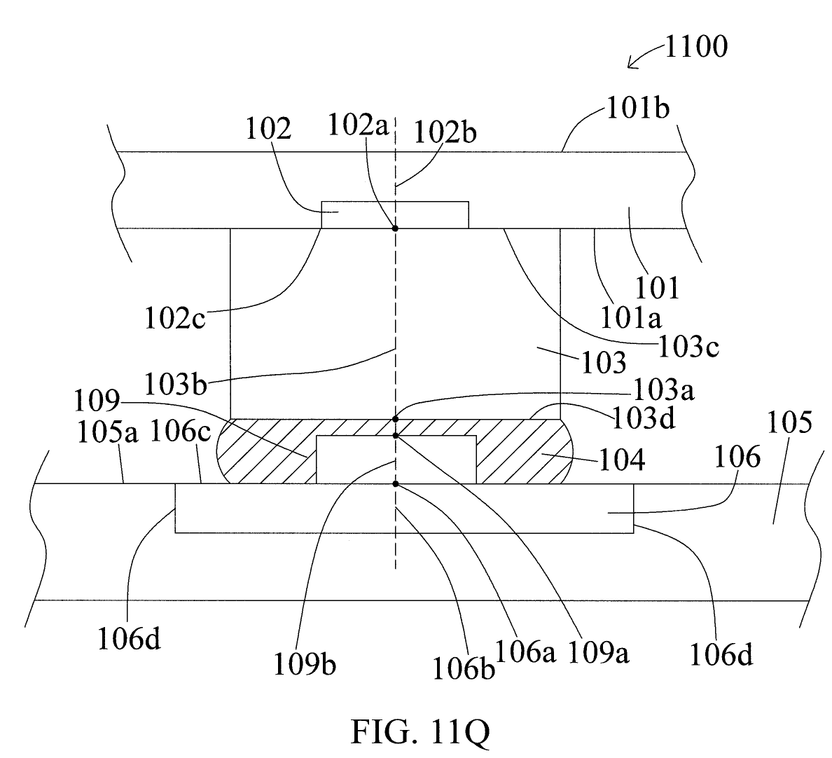

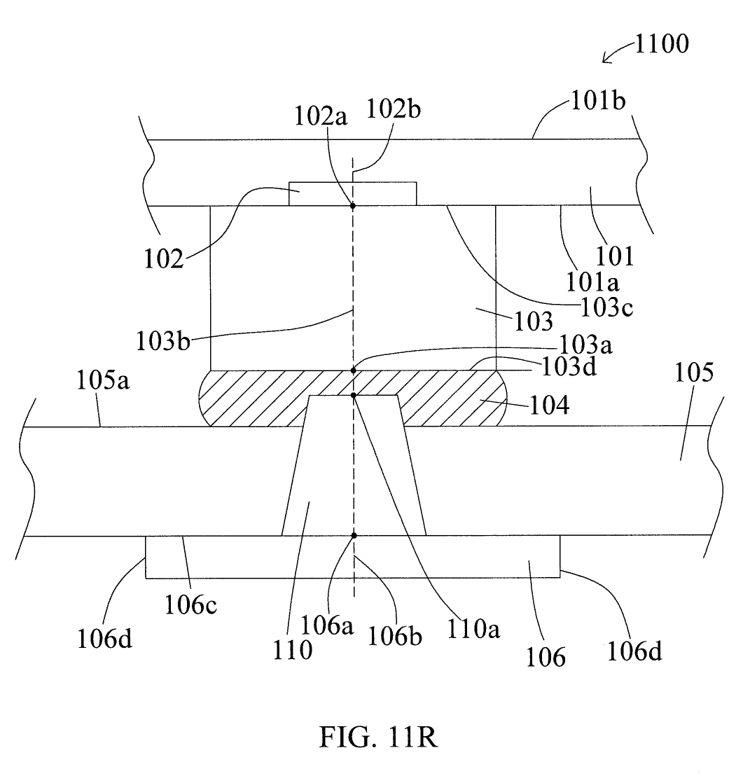

In operation 1001, a first substrate 101 is received or provided as in FIG. 11A. In some embodiments, the first substrate 101 is a silicon substrate. In some embodiments, a conductive pad 102 is formed and disposed over the substrate 101. In some embodiments, the conductive pad 102 is electrically connected with a circuitry internal to the first substrate 101. In some embodiments, the conductive pad 102 is defined with a geometric center 102a and a central axis 102b passing through the geometric center 102a.

In operation 1002, a connector 103 is disposed over the conductive pad 102 as in FIG. 11B. In some embodiments, the connector 103 is formed on a surface 101a of the substrate 101. The connector 103 is protruded from the conductive pad 102 or the substrate 101. In some embodiments, the conductive pad 102 is contacted with the connector 103, so that the conductive pad 102 is electrically connected with the connector 103.

In some embodiments, the connector 103 is formed so that a geometric center 103a of the connector 103 is deviated from the geometric center 102a of the conductive pad 102 in a predetermined distance Δd. A central axis 103b of the connector 103 is deviated from the central axis 102b of the conductive pad 102 in the predetermined distance Δd. Thus, the geometric center 103a is not aligned with the geometric center 102a, and the central axis 103b is also not aligned with the central axis 102b.

In some embodiments, a solder 104 is disposed over the connector 103. In some embodiments, the solder 104 is disposed on a top 103d of the connector 103 by pasting a solder material over a stencil or any other suitable operations.

In operation 1003, a second substrate 105 is provided or received as in FIG. 11C. In some embodiments, the second substrate 105 is a coreless substrate or an embedded pattern plating (EPP) substrate. In some embodiments, the second substrate 105 includes a conductive land 106. The conductive land 106 is disposed over a surface 105a of the second substrate 105. In some embodiments, the first substrate 101 is disposed above the second substrate 105. The surface 105a of the second substrate 105 and the conductive land 106 are facing the connector 103, the conductive pad 102 and the surface 101a of the substrate 101. In some embodiments, a geometric center 106a and a central axis 106b passing through the geometric center 106a are defined.

In some embodiments, the second substrate 105 includes a via 107 and a via pad 108 as in FIG. 11D. In some embodiments, the via 107 is tapered from the conductive land 106 to the via pad 108. In some embodiments, the via 107 is defined with a geometric center 107a and a central axis 107b, and the via pad 108 is defined with a geometric center 108a and a central axis 108b. In some embodiments, the geometric center 107a, the geometric center 108a and the geometric center 106a are aligned. In some embodiments, the central axis 107b, the central axis 108b and the central axis 106b are common.

In some embodiments, a guide pin 109 is provided over the conductive land 106 as in FIG. 11E. In some embodiments, the guide pin 109 is disposed on the conductive land 106 and is configured to protrude from the conductive land 106. In some embodiments, a geometric center 109a and a central axis 109b are defined. In some embodiments, the geometric center 109a of the guide pin 109 is aligned with the geometric center 106a of the conductive land 106, and the central axis 109b is common with the central axis 106b.

In some embodiments, a tapered metallic plug 110 is protruded from the surface 105a of the second substrate 105 as in FIG. 11F. In some embodiments, a geometric center 110a of the tapered metallic plug 110 is aligned with the geometric center 106a of the conductive land 106.

In operation 1004, a position of the first substrate 101 or the second substrate 105 is/are adjusted, thereby the geometric center 106a of the conductive land 106 is deviated from the geometric center 103a of the connector 103 in a predetermined distance Δd as in FIG. 11G. In some embodiments, the central axis 106b of the conductive land 106 is also deviated from the central axis 103b of the connector 103 in the predetermined distance Δd.

In some embodiments, the first substrate 101 or the second substrate 105 is/are displaced until the geometric center 106a of the conductive land 106 is deviated from the geometric center 103a of the connector 103 in the predetermined distance Δd. In some embodiments, the position of the first substrate 101 or the second substrate 105 is/are adjusted, such that the geometric center 102a of the conductive pad 102 is aligned with the geometric center 106a of the conductive land 106.

Similarly, the first substrate 101 or the second substrate 105 including the via 107 and the via pad 108 is/are displaced until the geometric center 106a of the conductive land 106 is deviated from the geometric center 103a of the connector 103 in the predetermined distance Δd, as shown in FIG. 11H.

In similar manner, the first substrate 101 or the second substrate 105 is/are displaced until the geometric center 109a of the guide pin 109 is deviated from the geometric center 103a of the connector 103 in the predetermined distance Δd, as shown in FIG. 11I.

In similar manner, the first substrate 101 or the second substrate 105 is/are displaced until the geometric center 110a of the tapered metallic plug 110 is deviated from the geometric center 103a of the connector 103 in the predetermined distance Δd, as shown in FIG. 11J.

In operation 1005, the connector 103 is bonded with the conductive land 106 as in FIG. 11K. FIG. 11K is in similar configuration as the semiconductor device 300 of FIG. 3. In some embodiments, the connector 103 is bonded with the conductive land 106 by the solder 104. In some embodiments, the connector 103 and the conductive land 106 are reflowed at a certain temperature to form an interconnect structure, such that the first substrate 101 is electrically connected with the second substrate 105. In some embodiments, the solder 104 is reflowed to bond the connector 103 with the conductive land 106. In some embodiments, the geometric center 106a of the conductive land 106 is deviated from the geometric center 103a of the connector 103 after the bonding operation.

In some embodiments as in FIG. 11L, the connector 103 is bonded with the conductive land 106 disposed above the via 107 and the via pad 108, in a manner similar to FIG. 11K. FIG. 11L is in similar configuration as the semiconductor device 400 of FIG. 4. In some embodiments as in FIG. 11M, the connector 103 is bonded with the conductive land 106 by the solder 104 and the guide pin 109, in a manner similar to FIG. 11K. FIG. 11M is in similar configuration as the semiconductor device 500 of FIG. 5. In some embodiments as in FIG. 11N, the connector 103 is bonded with the tapered metallic plug 110 by the solder 104, in a manner similar to FIG. 11K. FIG. 11N is in similar configuration as the semiconductor device 600 of FIG. 6.

In operation 1006, a temperature of the semiconductor device 1100 is adjusted so as to control elongation of the first substrate 101 and the second substrate 105, thereby the geometric center 103a of the connector 103 is substantially aligned with the geometric center 106a of the conductive land 106 as in FIG. 11O. FIG. 11O is in similar configuration as the semiconductor device 700 of FIG. 7. In some embodiments, the semiconductor device 1100 is heated to the temperature of about 200 to about 300 degree Celsius.

When the semiconductor device 1100 is heated, the first substrate 101 and the second substrate 105 are expanded and inflated in all direction. In some embodiments, the first substrate 101 and the second substrate 105 are elongated horizontally. In some embodiments, the second substrate 105 has a greater CTE than that of the first substrate 101, therefore the second substrate 105 has a greater expansion or elongation than the first substrate 101.

In some embodiments, the geometric center 103a of the connector 103 is aligned with the geometric center 106a of the conductive land 106 after the heating. The central axis 103b of the connector 103 is common with the central axis 106b of the conductive land 106. In some embodiments as in FIG. 11O, the geometric center 102a of the conductive pad 102 is aligned with the geometric center 103a of the connector 103 and the geometric center 106a of the conductive land 106 after the heating. FIG. 11O is in similar configuration as the semiconductor device 700 of FIG. 7.

In some embodiments, upon the adjustment of the temperature of the semiconductor device 1100, the connector 103 is controlled to be disposed within an external boundary 106d of the conductive land 106. When the semiconductor device 1100 is heated, the first substrate 101 and the second substrate 105 are expanded while the connector 103 has to be maintained within the conductive land 106, without exceeding the external boundary 106d.

Similarly, when the semiconductor device 1100 is heated, the geometric center 103a of the connector 103 is substantially aligned with the geometric center 106a of the conductive land 106 above the via 107 and the via pad 108 and as in FIG. 11P. FIG. 11P is in similar configuration as the semiconductor device 800 of FIG. 8.

In some embodiments, when the semiconductor device 1100 is heated, the geometric center 103a of the connector 103 is aligned with the geometric center 106a, the geometric center 107a of the via 107 and the geometric center 108a of the via pad 108. In some embodiments as in FIG. 11P, the geometric center 102a of the conductive pad 102 is aligned with the geometric center 103a of the connector 103, the geometric center 106a of the conductive land 106, the geometric center 107a of the via 107 and the geometric center 108a of the via pad 108 after the heating. FIG. 11P is in similar configuration as the semiconductor device 800 of FIG. 8.

In some embodiments, when the semiconductor device 1100 is heated, the geometric center 109a of the guide pin 109 is aligned with the geometric center 103a of the connector 103 as in FIG. 11Q. In some embodiments as in FIG. 11Q, the geometric center 102a of the conductive pad 102 is aligned with the geometric center 103a of the connector 103, the geometric center 106a of the conductive land 106 and the geometric center 109a of the guide pin 109 after the heating.

In some embodiments, when the semiconductor device 1100 is heated, the geometric center 110a of the tapered metallic plug 110 is aligned with the geometric center 103a of the connector 103 as in FIG. 11R. In some embodiments as in FIG. 11R, the geometric center 102a of the conductive pad 102 is aligned with the geometric center 103a of the connector 103, the geometric center 106a of the conductive land 106 and the geometric center 110a of the tapered metallic plug 110 after the heating.

The present invention provides a method for manufacturing a semiconductor device. The method includes following operations. A first substrate with a conductive pad is received. A connector is disposed over the conductive pad. A second substrate including a conductive land is provided. A position of the first substrate or the second substrate is adjusted thereby a geometric center of the conductive land is deviated from a geometric center of the connector in a deviated distance. The connector is bonded with the conductive land. A temperature of the semiconductor device is adjusted so as to control elongation of the first substrate and the second substrate, thereby the geometric center of the connector is substantially aligned with the geometric center of the conductive land.

The present invention further provides a method for manufacturing a semiconductor device. The method includes following operations. A first substrate with a conductive pad is received. The conductive pad has a geometric center and a central axis passing through the geometric center. A connector is formed over the conductive pad. The connector has a geometric center and a central axis passing through the geometric center. The central axis of the connector is deviated from the central axis of the conductive pad in a first distance. A second substrate including a conductive land is provided. The conductive land has a geometric center and a central axis passing through the geometric center. The first substrate is disposed over the second substrate with the connector and the conductive pad facing the conductive land. The central axis of the conductor land is substantially aligned with the central axis of the conductive pad, and deviated from the central axis of the connector in a second distance. The connector is bonded to the conductive land. A temperature of the semiconductor device is adjusted thereby the central axis of the connector is substantially aligned with the central axis of the conductive pad and the central axis of the conductive land.

The present invention further provides a method for manufacturing a semiconductor device. The method includes following operations. A first substrate with a conductive pad is received. A connector and a solder are disposed over the conductive pad. A first central axis passing through a geometric center of the conductive pad is deviated from a second central axis passing through a geometric center of the connector in a deviated distance. A second substrate including a conductive land formed therein is provided. A coefficient of thermal expansion (CTE) of the second substrate is greater than a CTE of the first substrate. The first substrate is disposed over the second substrate with the connector and the conductive pad facing the conductive land. The connector is disposed within an n external boundary of the conductive land. A third central axis passing through a geometric center of the conductive land is substantially aligned with the first central axis and deviated from the second central axis in the deviated distance. The connector is bonded to the conductive land by the solder. A temperature of the semiconductor device is adjusted thereby the connector is disposed within the external boundary of the conductive land. The first central axis, the second central axis and the third central axis are substantially aligned with each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
receiving a first substrate with a conductive pad;
disposing a connector over the conductive pad;
providing a second substrate including a conductive land therein;
adjusting a position of the first substrate or the second substrate, thereby a geometric center of the conductive land is deviated from a geometric center of the connector in a deviated distance;
bonding the connector with the conductive land; and
adjusting a temperature of the semiconductor device so as to control elongation of the first substrate and the second substrate, thereby the geometric center of the connector is substantially aligned with the geometric center of the conductive land.

2. The method according to claim 1, further comprising reflowing the connector and the conductive land to form an interconnect structure electrically connecting the first substrate and the second substrate.

3. The method according to claim 1, wherein the adjusting the temperature of the semiconductor device includes heating the semiconductor device to the temperature between about 200 and about 300 degrees Celsius.

4. The method according to claim 1, the adjusting the temperature of the semiconductor device includes controlling the connector disposed within an external boundary of the conductive land.

5. The method according to claim 1, further comprising:
providing a guide pin over the conductive land, wherein the guide pin is configured to protrude from the conductive land; and
aligning a geometric center of the guide pin with the geometric center of the connector.

6. The method according to claim 1, wherein the conductive land has a width of x μm, the connector has a width of y μm, and the deviated distance between the geometric center of the connector and the geometric center of the conductive land is Δd μm by the adjusting a position of the first substrate or the second substrate, and
wherein x≥y+2Δd.

7. A method for manufacturing a semiconductor device, comprising:
receiving a first substrate with a conductive pad, wherein the conductive pad has a geometric center and a central axis passing the geometric center;
forming a connector over the conductive pad, wherein the connector has a geometric center and a central axis passing through the geometric center, and the central axis of the connector is deviated from the central axis of the conductive pad in a first distance;
providing a second substrate including a conductive land therein, wherein the conductive land has a geometric center and a central axis passing through the geometric center;
disposing the first substrate over the second substrate with the connector and the conductive pad facing the conductive land, wherein the central axis of the conductive land is substantially aligned with the central axis of the conductive pad and is deviated from the central axis of the connector in a second distance;
bonding the connector to the conductive land; and
adjusting a temperature of the semiconductor device thereby the central axis of the connector is substantially aligned with the central axis of the conductive pad and the central axis of the conductive land.

8. The method according to claim 7, wherein the first distance is substantially equal to the second distance.

9. The method according to claim 7, wherein the second substrate comprises a via and a via pad disposed therein, and the via is tapered from the conductive land to the via pad.

10. The method according to claim 9, wherein the via has a geometric center and a central axis passing through the geometric center, the via pad has a geometric center and a central axis passing through the geometric center, the central axis of the via and the central axis of the via pad are substantially aligned with the central axis of the conductive land and central axis of the conductive pad, and are deviated from the central axis of the connector in the second distance prior to the adjusting of the temperature.

11. The method according to claim 10, wherein the central axis of the via and the central axis of the via pad are substantially aligned with the central axis of the conductive pad, the central axis of the connector and the central axis of the conductive land after the adjusting of the temperature.

12. The method according to claim 7, wherein the second substrate comprises a guide pin disposed over and protruded from the conductive land, the guide pin has a geometric center and a central axis passing through the geometric center, the central axis of the guide pin is substantially aligned with the central axis of the conductive land and the central axis of the conductive pad, and is deviated from the central axis of the connector prior to the adjusting of the temperature.

13. The method according to claim 12, wherein the central axis of the guide pin is substantially aligned with the central axis of the conductive pad, the central axis of the connector and the central axis of the conductive land after the adjusting of the temperature.

14. The method according to claim 7, wherein the second substrate comprises a first surface facing the first substrate and a second surface opposite to the first surface, and the conductive land is disposed over the second surface.

15. The method according to claim 14, wherein the second substrate comprises a tapered metallic plug penetrating the second substrate from the second surface to the first surface and protruded from the first surface, and the tapered metallic plug is coupled to the conductive land.

16. The method according to claim 15, wherein the tapered metallic plug has a geometric center and a central axis passing through the geometric center, the central axis of the tapered metallic plug is substantially aligned with the central axis of the conductive land and the central axis of the conductive pad, and is deviated from the central axis of the connector prior to the adjusting of the temperature.

17. The method according to claim 16, wherein the central axis of the tapered metallic plug is substantially aligned with the central axis of the conductive pad, the central axis of the connector and the central axis of the conductive land after the adjusting of the temperature.

18. A method for manufacturing a semiconductor device, comprising:
receiving a first substrate with a conductive pad;
disposing a connector and a solder over the conductive pad, wherein a first central axis passing through a geometric center of the conductive pad is deviated from a second central axis passing through a geometric center of the connector in a deviated distance;
providing a second substrate including a conductive land formed therein, wherein a coefficient of thermal expansion (CTE) of the second substrate is greater than a CTE of the first substrate;
disposing the first substrate over the second substrate with the connector and the conductive pad facing the conductive land, wherein the connector is disposed within an external boundary of the conductive land, and a third central axis passing through a geometric center of the conductive land is substantially aligned with the first central axis and deviated from the second central axis in the deviated distance;
bonding the connector to the conductive land by the solder; and
adjusting a temperature of the semiconductor device thereby the connector is disposed within the external boundary of the conductive land, and the first central axis, the second central axis and the third central axis are substantially aligned with each other.

19. The method according to claim 18, wherein the first substrate comprises a semiconductor substrate, and the second substrate comprises a coreless substrate or an embedded pattern plating (EPP) substrate.

20. The method according to claim 18, wherein the conductive land has a width of x μm, the connector has a width of y μm, the deviated distance is Δd μm, and wherein x≥y+2Δd.
